(19) United States
(12) Patent Application Publication
(10) Pub. No.: US 2020/0313013 A1
(43) Pub. Date: Oct. 1, 2020

(54) GALLIUM ARSENIDE SOLAR CELL HAVING A FUSED SILICA COVER

(71) Applicant: THE BOEING COMPANY, Chicago, IL (US)

(72) Inventors: Eric M. Rehder, Los Angeles, CA (US); Frank F. Ho, Yorba Linda, CA (US); Joel A. Schwartz, Glendale, CA (US)

(21) Appl. No.: 16/372,114

(22) Filed: Apr. 1, 2019

(51) Int. Cl. H01L 31/049; H01L 31/0687; H01L 31/0304; H01L 31/048; H01L 31/18

(52) U.S. Cl. CPC H01L 31/049; H01L 31/0687; H01L 31/1864; H01L 31/0481; H01L 31/1852; H01L 31/0304

(57) ABSTRACT

A solar cell includes a Germanium wafer having a first side and a second side. The first side has properties consistent with a grinding operation, and edges of the Germanium wafer have properties consistent with a diamond-coated saw blade cut. The Germanium wafer has a thickness of approximately two-hundred five micrometers. The solar cell also includes a Gallium Arsenide-based triple junction solar cell coupled to the second side of the Germanium wafer. The solar cell also includes a fused silica cover coupled to the Gallium Arsenide-based triple junction solar cell via a silicone-based adhesive.

### FIELD OF THE DISCLOSURE

The present disclosure is related to a solar cell.

### BACKGROUND

Satellite missions are exposed to proton and electron radiation. For example, in a Medium Earth Orbit (MEO), there is a higher density of protons and electrons that degrade components, such as a solar cell cover glass, than at ground level. Conventional solar cells used in satellites use a Borosilicate cover glass. However, in the MEO, the Borosilicate cover glass darkens due to exposure to proton and electron radiation and, as a result, the solar cell (or solar array) has a reduced power output. Fused silica experiences less darkening due to proton and electron radiation than Borosilicate glass materials. However, fused silica has a coefficient of thermal expansion that is significantly different than the coefficient of thermal expansion of Ge and GaAs used to form space solar cells.

### SUMMARY

According to one implementation of the present disclosure, a method of fabricating a solar cell includes performing a grinding operation on a first side of a Germanium wafer to smooth the first side of the Germanium wafer and to reduce a thickness of the Germanium wafer to approximately two-hundred five micrometers. The method also includes depositing materials to form a Gallium Arsenide-based triple junction solar cell on a second side of the Germanium wafer. The second side is opposite the first side. The method further includes cutting, using a diamond-coated saw blade, the Germanium wafer with the Gallium Arsenide-based triple junction solar cell to generate a Germanium-backed Gallium Arsenide solar cell. The method also includes coupling a fused silica cover to the Germanium-backed Gallium Arsenide solar cell using a silicone-based adhesive.

According to another implementation of the present disclosure, a solar cell includes a Germanium wafer having a first side and a second side. The first side has properties consistent with a grinding operation, and edges of the Germanium wafer have properties consistent with a diamond-coated saw blade cut. The Germanium wafer has a thickness of approximately two-hundred five micrometers. The solar cell also includes a Gallium Arsenide-based triple junction solar cell coupled to the second side of the Germanium wafer. The solar cell also includes a fused silica cover coupled to the Gallium Arsenide-based triple junction solar cell via a silicone-based adhesive.

One advantage of the above-described implementations is improved power output of a solar cell. For example, the fused silica cover is less subject to radiation darkening than Borosilicate cover glass which results in improved power output on orbit. In addition, the Germanium-backed Gallium Arsenide solar cell has characteristics that reduce the likelihood of failure due to thermal expansion mismatch of the Germanium-backed Gallium Arsenide solar cell and the fused silica cover. As non-limiting examples, the Germanium-backed Gallium Arsenide solar cell has increased thickness providing greater protection against stress and the backside polishing of the Germanium-backed Gallium Arsenide solar cell reduces surface roughness. For example, the backside etching and polishing can reduce a surface roughness metric of the Germanium-backed Gallium Arsenide solar cell from 50 nanometers (nm) to 17 nm. Reduced surface roughness can result in fewer sites for cracks to initiate on the backside of the Germanium-backed Gallium Arsenide solar cell. Additionally, the features, functions, and advantages that have been described can be achieved independently in various implementations or may be combined in yet other implementations, further details of which are disclosed with reference to the following description and drawings.

### BRIEF DESCRIPTION OF THE DRAWINGS

FIG. 1A illustrates an example of a Germanium wafer used to fabricate a Germanium-backed Gallium Arsenide solar cell having a fused silica cover;

FIG. 1B illustrates an example of performing a grinding operation on a first side of the Germanium wafer;

FIG. 1C illustrates an example of performing a polishing operation on the Germanium wafer;

FIG. 1D illustrates an example of depositing a Gallium Arsenide material on the second side of the Germanium wafer to generate a Gallium Arsenide-based triple junction solar cell;

FIG. 2A illustrates an example of the Germanium wafer with the Gallium Arsenide-based triple junction solar cell;

FIG. 2B illustrates an example of cutting the Germanium wafer with the Gallium Arsenide-based triple junction solar cell;

FIG. 2C illustrates an example of the Germanium-backed Gallium Arsenide solar cell;

FIG. 3A illustrates an example of applying a silicone-based adhesive on the Germanium-backed Gallium Arsenide solar cell;

FIG. 3B illustrates an example of coupling a fused silica cover to the Germanium-backed Gallium Arsenide solar cell;

FIG. 4 illustrates an example of performing a low-temperature adhesive curing process; and

FIG. 5 is a flowchart of a method of fabricating a Germanium-backed Gallium Arsenide solar cell having a fused silica cover.

### DETAILED DESCRIPTION

Particular embodiments of the present disclosure are described below with reference to the drawings. In the description, common features are designated by common reference numbers throughout the drawings.

The figures and the following description illustrate specific exemplary embodiments. It will be appreciated that those skilled in the art will be able to devise various arrangements that, although not explicitly described or shown herein, embody the principles described herein and are included within the scope of the claims that follow this description. Furthermore, any examples described herein are intended to aid in understanding the principles of the disclosure and are to be construed as being without limitation. As a result, this disclosure is not limited to the specific embodiments or examples described below, but by the claims and their equivalents.

As used herein, various terminology is used for the purpose of describing particular implementations only and is not intended to be limiting. For example, the singular forms “a,” “an,” and “the” are intended to include the plural forms as well, unless the context clearly indicates otherwise. Further, the terms “comprise,” “comprises,” and “comprising” are used interchangeably with “include,” “includes,” or “including.” Additionally, the term “wherein” is used interchangeably with the term “where.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to a grouping of one or more elements, and the term “plurality” refers to multiple elements.

As used herein, “generating”, “calculating”, “using”, “selecting”, “accessing”, and “determining” are interchangeable unless context indicates otherwise. For example, “generating”, “calculating”, or “determining” a parameter (or a signal) can refer to actively generating, calculating, or determining the parameter (or the signal) or can refer to using, selecting, or accessing the parameter (or signal) that is already generated, such as by another component or device. As used herein, “coupled” can include “communicatively coupled,” “electrically coupled,” or “physically coupled,” and can also (or alternatively) include any combinations thereof. Two devices (or components) can be coupled (e.g., communicatively coupled, electrically coupled, or physically coupled) directly or indirectly via one or more other devices, components, wires, buses, networks (e.g., a wired network, a wireless network, or a combination thereof), etc. Two devices (or components) that are electrically coupled can be included in the same device or in different devices and can be connected via electronics, one or more connectors, or inductive coupling, as illustrative, non-limiting examples. In some implementations, two devices (or components) that are communicatively coupled, such as in electrical communication, can send and receive electrical signals (digital signals or analog signals) directly or indirectly, such as via one or more wires, buses, networks, etc. As used herein, “directly coupled” is used to describe two devices that are coupled (e.g., communicatively coupled, electrically coupled, or physically coupled) without intervening components.

The techniques described herein enable improved power output of a solar cell. For example, the fused silica cover is less subject to radiation darkening than Borosilicate cover glass which results in improved power output on orbit. In addition, the Germanium-backed Gallium Arsenide solar cell has characteristics that reduce the likelihood of failure due to thermal expansion mismatch of the Germanium-backed Gallium Arsenide solar cell and the fused silica cover. As non-limiting examples, the Germanium-backed Gallium Arsenide solar cell has increased thickness providing greater protection against stress and the backside polishing of the Germanium-backed Gallium Arsenide solar cell reduces surface roughness. Reduced surface roughness can result in fewer sites for cracks to initiate on the backside of the Germanium-backed Gallium Arsenide solar cell.

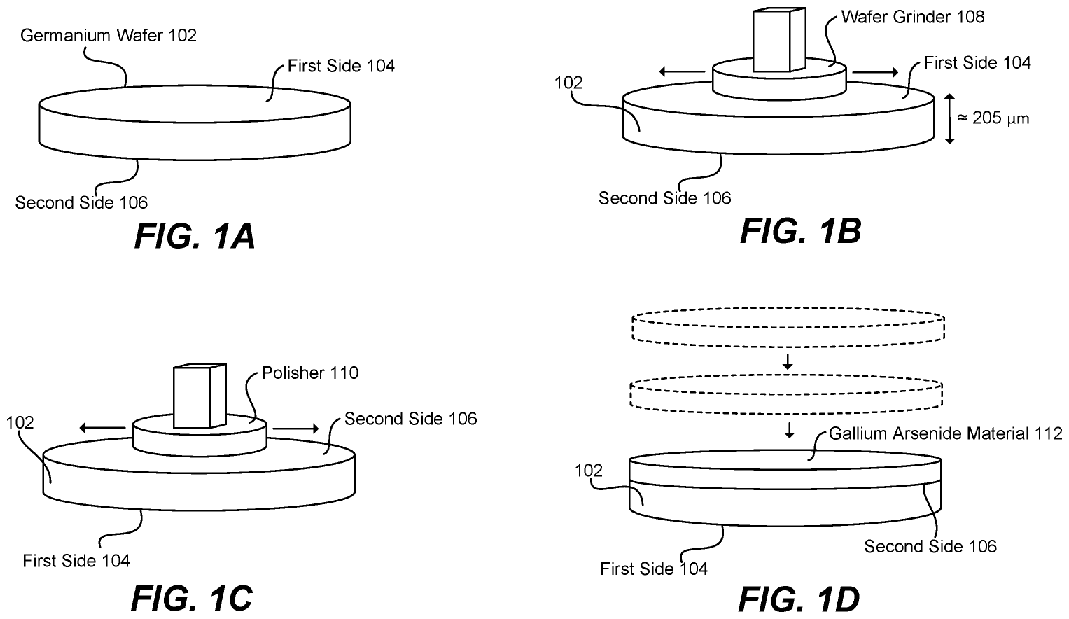

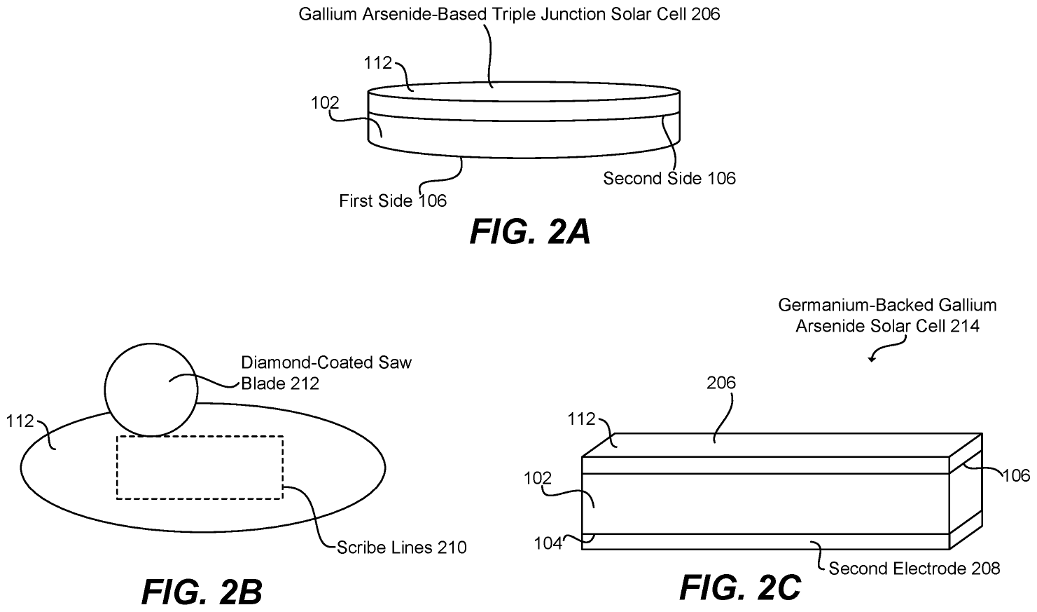

FIG. 1A illustrates an example of a Germanium wafer 102 that is used to fabricate a Germanium-backed Gallium Arsenide solar cell having a fused silica cover. The Germanium wafer 102 has a first side 104 and a second side 106. In the example of FIG. 1, the first side 104 and the second side 106 have relatively rough surfaces (e.g., due to a wafer sawing process used to form the Germanium wafer 102). As described below, portions of the Germanium wafer 102 are used as a substrate for a Germanium-backed Gallium Arsenide solar cell, such as a Germanium-backed Gallium Arsenide solar cell 214 illustrated in FIG. 2C, that is operable to function using a fused silica cover without material degradation, cracks, or decreased performance.

FIG. 1B illustrates an example of performing a grinding operation on a first side of the Germanium wafer 102. For example, in FIG. 1B, a wafer grinder 108 performs a grinding operation on the first side 104 of the Germanium wafer 102 to smooth the first side 104 of the Germanium wafer 102 and to reduce a thickness of the Germanium wafer 102 to approximately two-hundred five (205) micrometers (μm). Thus, the first side 104 of the Germanium wafer 102 has properties (e.g., smoothness properties) consistent with the grinding and polishing operation. The thickness of the Germanium wafer 102 can increase the strength of the resulting Germanium-backed Gallium Arsenide solar cell 114 as compared to typical solar cells based on substrate thickness of one-hundred forty (140) μm. Additionally, performing the grinding and polishing operation (e.g., a backside grind wafer-thinning operation) on the first side 104 of the Germanium wafer 102 reduces a roughness metric and increases a breakage strength associated with the resulting Germanium-backed Gallium Arsenide solar cell 114. For example, because a typical solar cell undergoes backside etching, the typical solar cell has a relatively rough backside that is a tremendous source for stress concentrators that can yield to cracks and decreased performance. The grinding and polishing operation described with respect to FIG. 1B alleviates stress concentrators that yield to cracks and decreased performance.

FIG. 1C illustrates an example of performing a grinding and polishing operation a second side of the Germanium wafer. For example in FIG. 1C, a polisher 110 performs a grinding and polishing operation on the second side 106 of the Germanium wafer 102 to smooth the second side 106 of the Germanium wafer 102. According to one implementation, the polishing operation includes a chemical-mechanical polishing (CMP) operation to planarize the second side 106. Smoothing the second side 106 of the Germanium wafer 102 reduces a roughness metric and increases a breakage strength associated with the resulting Germanium-backed Gallium Arsenide solar cell 114.

FIG. 1D illustrates an example of depositing a Gallium Arsenide material 112 on the second side of the Germanium wafer 102. For example, in FIG. 1D, a Gallium Arsenide wafer is deposited on the second side 106 of the Germanium wafer 102 using a wafer bonding operation. According to another implementation, the Gallium Arsenide material 112 is deposited using a deposition process (e.g., a chemical vapor deposition (CVD) process). The Gallium Arsenide material 112 has a coefficient of thermal expansion (CTE) of 6 parts per million per degree Centigrade (ppm/C) that is substantially similar to the CTE of the Germanium wafer 102 (e.g., 6 ppm/C). The similar CTEs result in reduced thermal stress for the resulting Germanium-backed Gallium Arsenide solar cell 114.

FIG. 2A illustrates an example of the Germanium wafer 102 with a Gallium Arsenide-based triple junction solar cell 206. For example, the Gallium Arsenide material 112 can form the Gallium Arsenide-based triple junction solar cell 206 on the second side 106 of the Germanium wafer 102. The Gallium Arsenide-based triple junction solar cell 206 has an area of approximately seventy-five square centimeters and is rectangular. The Gallium Arsenide-based triple junction solar cell 206 is operable to convert light energy into electricity using a photovoltaic effect.

FIG. 2B illustrates an example of cutting the Germanium wafer with the Gallium Arsenide-based triple junction solar cell. For example, in FIG. 2C, a diamond-coated saw blade 212 cuts the Germanium wafer 102 with the Gallium Arsenide-based triple junction solar cell 206 to generate the Germanium-backed Gallium Arsenide solar cell 214 illustrated in FIG. 2C. As a result, edges of the Germanium wafer 102 and edges of the Gallium Arsenide-based triple junction solar cell 206 have properties consistent with a diamond-coated saw blade cut. To illustrate, the diamond-coated saw blade 212 cuts a narrow channel (with a smooth edge) into the Germanium wafer 102 with the Gallium Arsenide-based triple junction solar cell 206. As a result, a defective region associated with the Gallium Arsenide material 112 is smaller than would be present if a scribe and snap operation were used for dicing the Germanium wafer 102. As a result of the smaller defective region, the Germanium-backed Gallium Arsenide solar cell 214 is stronger than a typical solar cell and is able to withstand thermal stresses resulting from assembly with a fused silica cover, which has a CTE of 0 ppm/C. Although one Germanium-backed Gallium Arsenide solar cell 214 is depicted in FIG. 2C, the diamond-coated saw blade 212 can be used in a dicing operation to form multiple Germanium-backed Gallium Arsenide solar cells having a similar configuration as the Germanium-backed Gallium Arsenide solar cell 214 depicted in FIG. 2C.

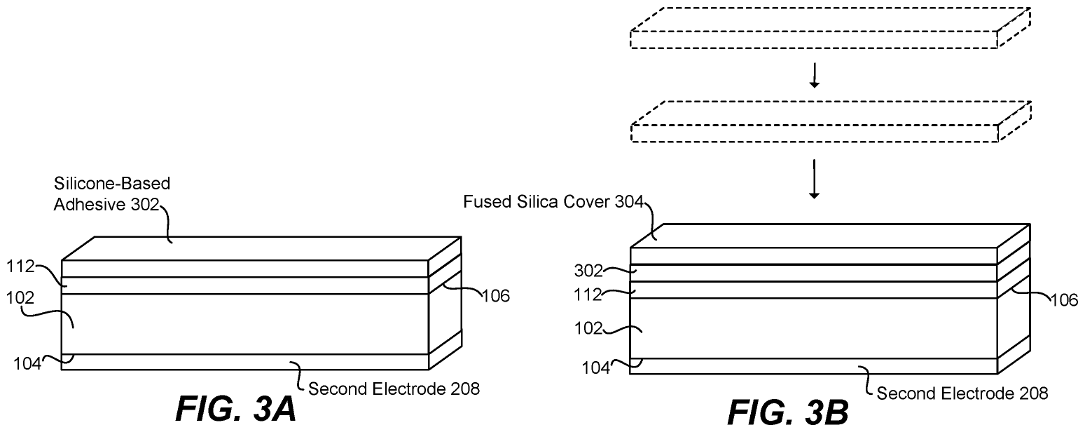

FIG. 3A illustrates an example of applying a silicone-based adhesive on the Germanium-backed Gallium Arsenide solar cell. For example, in FIG. 3A, a silicone-based adhesive 302 is applied to the Germanium-backed Gallium Arsenide solar cell 214. In particular, the silicone-based adhesive 302 is applied on top of the Gallium Arsenide-based triple junction solar cell 206. The silicone-based adhesive 302 is a transparent, colorless, low viscosity fluid. According to one implementation, the silicone-based adhesive 302 is the DOW CORNING® 93-500 Space-Grade Encapsulant.

FIG. 3B illustrates an example of coupling a fused silica cover to the Germanium-backed Gallium Arsenide solar cell. For example, in FIG. 3B, a fused silica cover 304 is coupled to the Germanium-backed Gallium Arsenide solar cell 214 using the silicone-based adhesive 302.

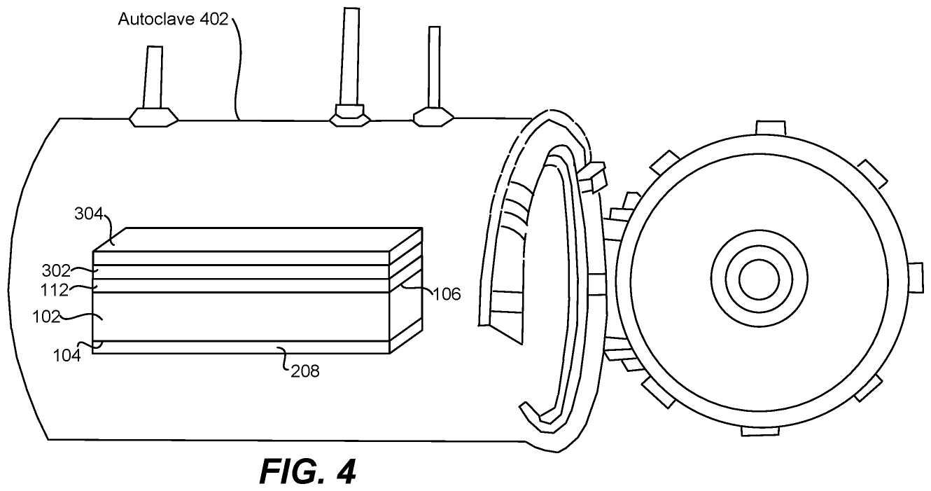

FIG. 4 illustrates an example of performing a low-temperature adhesive curing process. For example, in FIG. 4, the Germanium-backed Gallium Arsenide solar cell 214 with the fused silica cover 304 is inserted into an autoclave 402. The autoclave 404 performs a low-temperature adhesive curing process to cure the silicone-based adhesive 302 and adhere the fused silica cover 304 to the Germanium-backed Gallium Arsenide solar cell 214. For example, performing the low-temperature adhesive curing process, as opposed to a high temperature adhesive curing process, reduces strain and stresses in the resulting Germanium-backed Gallium Arsenide solar cell 214 with the fused silica cover 304. In particular, a low-temperature adhesive cure results in decreased cross-linking between the silicone-based adhesive 302 and the other components of the Germanium-backed Gallium Arsenide solar cell 214. The low-temperature adhesive cure also results in increased flexibility to strains between the fused silica cover 304 and the Germanium-backed Gallium Arsenide solar cell 214 due to differential thermal expansion. According to one implementation, the low-temperature adhesive curing process is performed at twenty-five (25) degrees Celsius for twenty-four hours. According to another implementation, the low-temperature adhesive curing process is performed at sixty-five (65) degrees Celsius for four hours. According to another implementation, the low-temperature adhesive curing process is performed at one-hundred (100) degrees Celsius for one hour. According to another implementation, the low-temperature adhesive curing process is performed at one-hundred fifty (150) degrees Celsius for fifteen minutes.

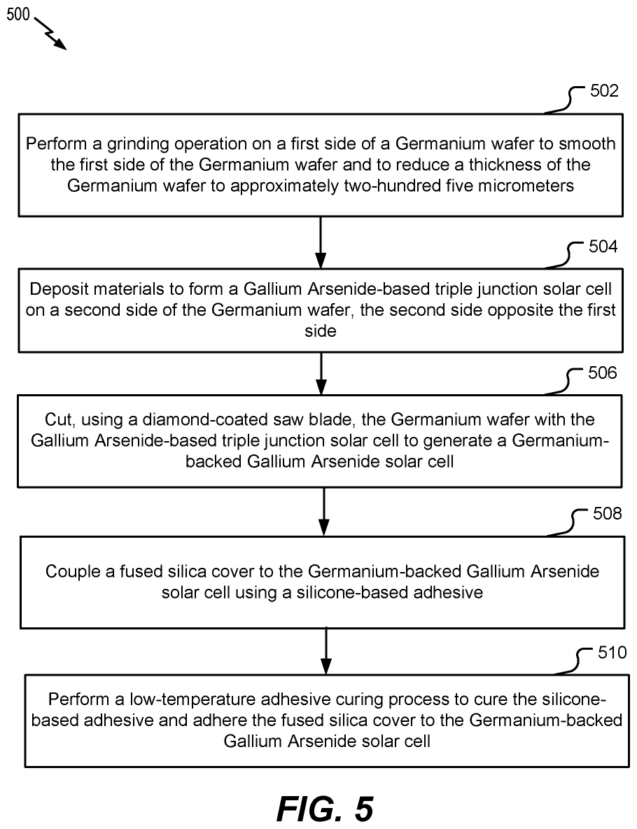

FIG. 5 is a flowchart of a method 500 of fabricating a Germanium-backed Gallium Arsenide solar cell having a fused silica cover. The method 500 can be performed using the techniques described with respect to FIGS. 1A-4.

The method 500 includes performing a grinding operation on a first side of a Germanium wafer to smooth the first side of the Germanium wafer and to reduce a thickness of the Germanium wafer to approximately two-hundred five micrometers, at 502. For example, in FIG. 1B, the wafer grinder 108 performs the grinding operation on the first side 104 of the Germanium wafer 102 to smooth the first side 104 of the Germanium wafer 102 and to reduce the thickness of the Germanium wafer 102 to approximately two-hundred five (205) μm. The thickness of the Germanium wafer 102 can increase the strength of the resulting Germanium-backed Gallium Arsenide solar cell 114 compared to a typical solar cell having a typical substrate thickness of one-hundred forty (140) μm. Additionally, performing the grinding operation (e.g., a backside grind wafer-thinning operation) on the first side 104 of the Germanium wafer 102 reduces a roughness metric and increases a breakage strength associated with the resulting Germanium-backed Gallium Arsenide solar cell 114. For example, because a typical solar cell undergoes backside etching, the typical solar cell has a relatively rough backside that is a tremendous source for stress concentrators that can yield to cracks and decreased performance. The grinding operation described with respect to FIG. 1B alleviates stress concentrators that yield to cracks and decreased performance.

The method 500 also includes depositing materials to form a Gallium Arsenide-based triple junction solar cell on a second side of the Germanium wafer, at 504. The second side is opposite the first side. For example, in FIG. 1D, the Gallium Arsenide material 112 is deposited on the second side 106 of the Germanium wafer 102 to form the Gallium Arsenide-based triple junction solar cell 206 on the second side 106 of the Germanium wafer 102. According to one implementation, the Gallium Arsenide material 112 is deposited using a deposition process (e.g., a CVD process).

The method 500 further includes cutting, using a diamond-coated saw blade, the Germanium wafer with the Gallium Arsenide-based triple junction solar cell to generate a Germanium-backed Gallium Arsenide solar cell, at 506. For example, in FIG. 2C, the diamond-coated saw blade 212 cuts the Germanium wafer 102 with the Gallium Arsenide-based triple junction solar cell 206 to generate the Germanium-backed Gallium Arsenide solar cell 214 illustrated in FIG. 2C. To illustrate, the diamond-coated saw blade 212 cuts a narrow channel into the Germanium wafer 102 with the Gallium Arsenide-based triple junction solar cell 206. As a result, a defective region associated with the Gallium Arsenide material 112 is smaller than it would be present if a scribe and snap operation were used for dicing the Germanium wafer 102. As a result of the smaller defective region, the Germanium-backed Gallium Arsenide solar cell 214 is stronger than a typical solar cell and is able to withstand thermal stresses resulting from assembly with a fused silica cover.

The method 500 also includes coupling a fused silica cover to the Germanium-backed Gallium Arsenide solar cell using a silicone-based adhesive, at 508. For example, in FIG. 3A, the silicone-based adhesive 302 is applied to the Germanium-backed Gallium Arsenide solar cell 214. In particular, the silicone-based adhesive 302 is applied on top of the Gallium Arsenide-based triple junction solar cell 206. In FIG. 3B, the fused silica cover 304 is coupled to the Germanium-backed Gallium Arsenide solar cell 214 using the silicone-based adhesive 302.

The method 500 also includes performing a low-temperature adhesive curing process to cure the silicone-based adhesive and adhere the fused silica cover to the Germanium-backed Gallium Arsenide solar cell, at 510. For example, in FIG. 4, the Germanium-backed Gallium Arsenide solar cell 214 with the fused silica cover 304 is inserted into an autoclave 402. The autoclave 404 performs a low-temperature adhesive curing process to cure the silicone-based adhesive 302 and adhere the fused silica cover 304 to the Germanium-backed Gallium Arsenide solar cell 214. For example, performing the low-temperature adhesive curing process, as opposed to a high temperature adhesive curing process, reduces strain and stresses in the resulting Germanium-backed Gallium Arsenide solar cell 214 with the fused silica cover 304.

According to one implementation, the method 500 includes performing a polishing operation on the second side of the Germanium wafer prior to depositing the materials. For example, in FIG. 1C, the polisher 110 performs the polishing operation on the second side 106 of the Germanium wafer 102 to smooth the second side 106 of the Germanium wafer 102. According to one implementation, the polishing operation includes a CMP operation. Smoothing the second side 106 of the Germanium wafer 102 reduces a roughness metric and increases a breakage strength associated with the resulting Germanium-backed Gallium Arsenide solar cell 114.

The illustrations of the examples described herein are intended to provide a general understanding of the structure of the various implementations. The illustrations are not intended to serve as a complete description of all of the elements and features of apparatus and systems that utilize the structures or methods described herein. Many other implementations may be apparent to those of skill in the art upon reviewing the disclosure. Other implementations may be utilized and derived from the disclosure, such that structural and logical substitutions and changes may be made without departing from the scope of the disclosure. For example, method operations may be performed in a different order than shown in the figures or one or more method operations may be omitted. Accordingly, the disclosure and the figures are to be regarded as illustrative rather than restrictive.

Moreover, although specific examples have been illustrated and described herein, it should be appreciated that any subsequent arrangement designed to achieve the same or similar results may be substituted for the specific implementations shown. This disclosure is intended to cover any and all subsequent adaptations or variations of various implementations. Combinations of the above implementations, and other implementations not specifically described herein, will be apparent to those of skill in the art upon reviewing the description.

The Abstract of the Disclosure is submitted with the understanding that it will not be used to interpret or limit the scope or meaning of the claims. In addition, in the foregoing Detailed Description, various features may be grouped together or described in a single implementation for the purpose of streamlining the disclosure. Examples described above illustrate but do not limit the disclosure. It should also be understood that numerous modifications and variations are possible in accordance with the principles of the present disclosure. As the following claims reflect, the claimed subject matter may be directed to less than all of the features of any of the disclosed examples. Accordingly, the scope of the disclosure is defined by the following claims and their equivalents.

What is claimed is:

1. A method of fabricating a solar cell, the method comprising:
performing a grinding operation on a first side of a Germanium wafer to smooth the first side of the Germanium wafer and to reduce a thickness of the Germanium wafer to approximately two-hundred five micrometers;
depositing materials to form a Gallium Arsenide-based triple junction solar cell on a second side of the Germanium wafer, the second side opposite the first side;
cutting, using a diamond-coated saw blade, the Germanium wafer with the Gallium Arsenide-based triple junction solar cell to generate a Germanium-backed Gallium Arsenide solar cell;
coupling a fused silica cover to the Germanium-backed Gallium Arsenide solar cell using a silicone-based adhesive; and
performing a low-temperature adhesive curing process to cure the silicone-based adhesive and adhere the fused silica cover to the Germanium-backed Gallium Arsenide solar cell.

2. The method of claim 1, further comprising performing a polishing operation on the second side of the Germanium wafer prior to depositing the materials.

3. The method of claim 2, wherein the polishing operation comprises a chemical-mechanical polishing operation.

4. The method of claim 3, wherein depositing the materials to form the Gallium Arsenide-based triple junction solar cell comprises depositing a Gallium Arsenide wafer on the second side of the Germanium wafer.

5. The method of claim 1, wherein the silicone-based adhesive is a transparent, colorless, low viscosity fluid.

6. The method of claim 1, wherein the low-temperature adhesive curing process is performed at twenty-five degrees Celsius for twenty-four hours.

7. The method of claim 1, wherein the low-temperature adhesive curing process is performed at sixty-five degrees Celsius for four hours.

8. The method of claim 1, wherein the low-temperature adhesive curing process is performed at one-hundred degrees Celsius for one hour.

9. The method of claim 1, wherein the low-temperature adhesive curing process is performed at one-hundred fifty degrees Celsius for fifteen minutes.

10. The method of claim 1, wherein an area of the Gallium Arsenide-based triple junction solar cell is approximately seventy-five square centimeters.

11. The method of claim 1, wherein the Gallium Arsenide-based triple junction solar cell is rectangular.

12. A solar cell comprising:
a Germanium wafer having a first side and a second side, the first side having properties consistent with a grinding operation, edges of the Germanium wafer having properties consistent with a diamond-coated saw blade cut, and the Germanium wafer having a thickness of approximately two-hundred five micrometers;
a Gallium Arsenide-based triple junction solar cell coupled to the second side of the Germanium wafer; and
a fused silica cover coupled to the Gallium Arsenide-based triple junction solar cell via a silicone-based adhesive.

13. The solar cell of claim 12, wherein the Gallium Arsenide-based triple junction solar cell comprises a Gallium Arsenide wafer.

14. The solar cell of claim 12, wherein the silicone-based adhesive is a transparent, colorless, low viscosity fluid.

15. The solar cell of claim 12, wherein an area of the Gallium Arsenide-based triple junction solar cell is approximately seventy-five square centimeters.

16. The solar cell of claim 12, wherein the Gallium Arsenide-based triple junction solar cell is rectangular.
